(19) United States
(12) Patent Application Publication
(10) Pub. No.: US 2022/0199410 A1
(43) Pub. Date: Jun. 23, 2022

(54) CONFORMAL AMORPHOUS CARBON LAYER ETCH WITH SIDE-WALL PASSIVATION

(71) Applicant: Tokyo Electron Limited, Tokyo (JP)

(72) Inventors: Du Zhang, Albany, NY (US); Shihsheng Chang, Albany, NY (US); Yunho Kim, Albany, NY (US); Mingmei Wang, Albany, NY (US); Andrew Metz, Albany, NY (US)

(21) Appl. No.: 17/550,182

(22) Filed: Dec. 14, 2021

Related U.S. Application Data
(60) Provisional application No. 63/128,630, filed on Dec. 21, 2020.

(51) Int. Cl. H01L 21/3065; H01L 21/308

(52) U.S. Cl. CPC H01L 21/3065; H01L 21/308

(57) ABSTRACT

A method for etching high-aspect ratio recessed features in an amorphous carbon layer is presented. The method includes providing a substrate containing an amorphous carbon layer and a patterned mask layer, plasma-etching a recessed feature through less than an entire thickness of the amorphous carbon layer using the patterned mask, forming a passivation layer on a sidewall of the etched amorphous carbon layer in the recessed feature by exposing the substrate to a passivation gas in the absence of a plasma, and repeating the plasma-etching and forming the passivation layer at least once to extend the recessed feature in the amorphous carbon layer.

### CROSS REFERENCE TO RELATED PATENTS AND APPLICATIONS

This application claims priority to and the benefit of the filing date of U.S. Provisional Patent Application No. 63/128,630, filed Dec. 21, 2020, which application is incorporated herein by reference in its entirety.

### FIELD OF INVENTION

The present invention relates to the field of semiconductor manufacturing and semiconductor devices, and more particularly, to a method of anisotropic amorphous carbon layer etch with side-wall passivation for semiconductor manufacturing.

### BACKGROUND OF THE INVENTION

The increase in circuit density in semiconductor devices has led to reduction in critical dimension (CD) of etched features. Typically, a circuit pattern is formed by plasma-etching a target film using a patterned mask. The need for increased aspect ratio (AR) in high-aspect ratio contact (HARC) etching of the target film requires a thick mask structure and this, in turn, requires a high etch rate when forming the mask structure. Further, maintaining the CD and preventing lateral etching of the mask structure is crucial, as well as avoiding roughness and striation formation on sidewalls of the mask structure. New methods are needed that provide conformal sidewall passivation and protection during plasma-etching of the mask structure.

### SUMMARY OF THE INVENTION

A method for etching high-aspect ratio recessed features in an amorphous carbon layer is provided in several embodiments. The amorphous carbon layer may subsequently be used as a mask to etch an underlying target film.

According to one embodiment, an etching method is described that includes providing a substrate containing an amorphous carbon layer and a patterned mask layer, plasma-etching a recessed feature through less than an entire thickness of the amorphous carbon layer using the patterned mask, forming a conformal passivation layer on a sidewall of the etched amorphous carbon layer in the recessed feature by exposing the substrate to a passivation gas in the absence of a plasma, and repeating the plasma-etching and forming the passivation layer at least once to extend the recessed feature in the amorphous carbon layer. The repeating may be performed until the recessed feature extends through the entire thickness of the amorphous carbon layer. The passivation gas can include a boron-containing gas, a silicon-containing gas, or an aluminum-containing gas, that thermally reacts with the amorphous carbon layer to form a conformal passivation layer.

### DETAILED DESCRIPTION OF THE DRAWINGS

In the accompanying drawings:

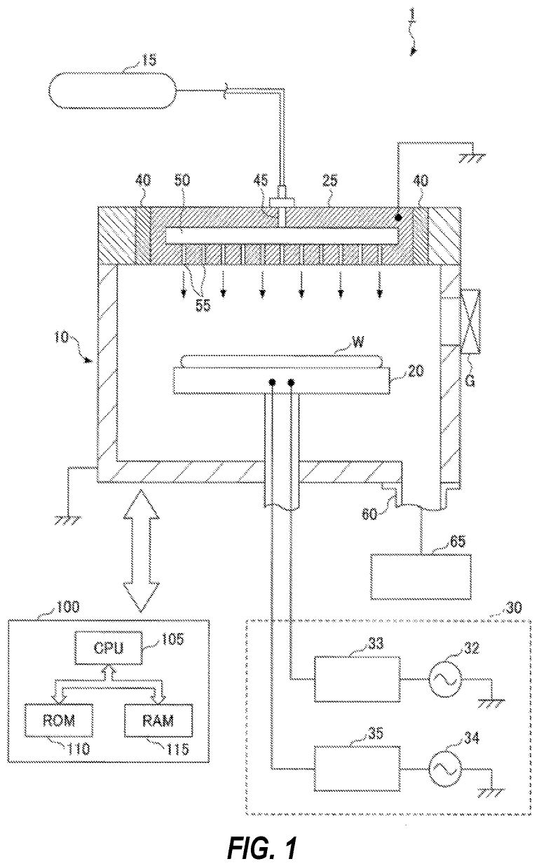

FIG. 1 schematically shows a plasma processing system according to one embodiment of the invention;

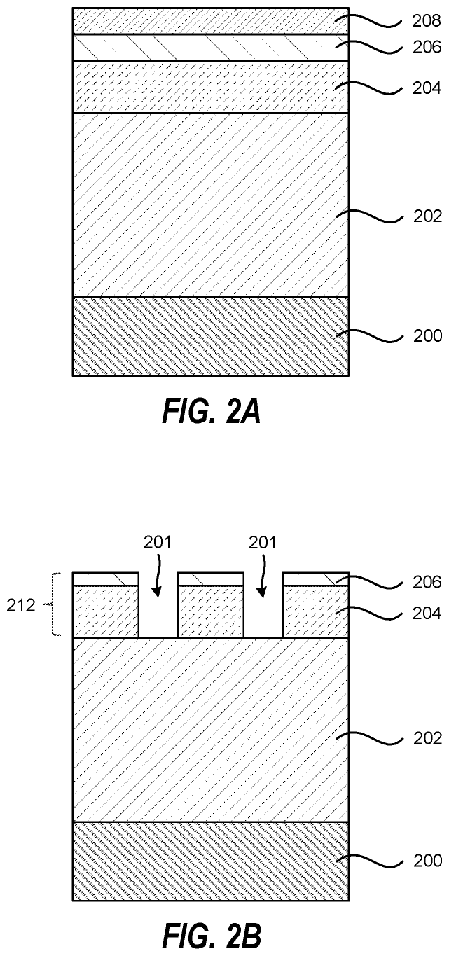

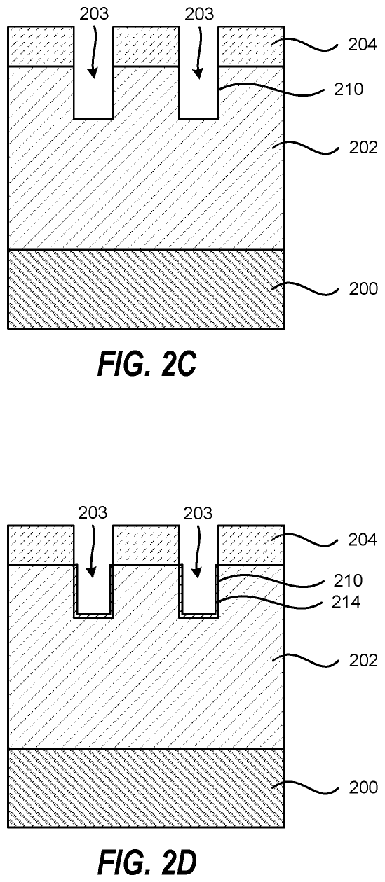

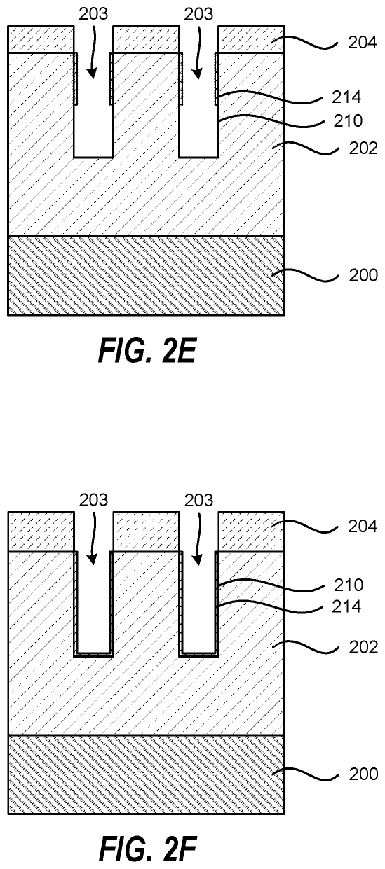

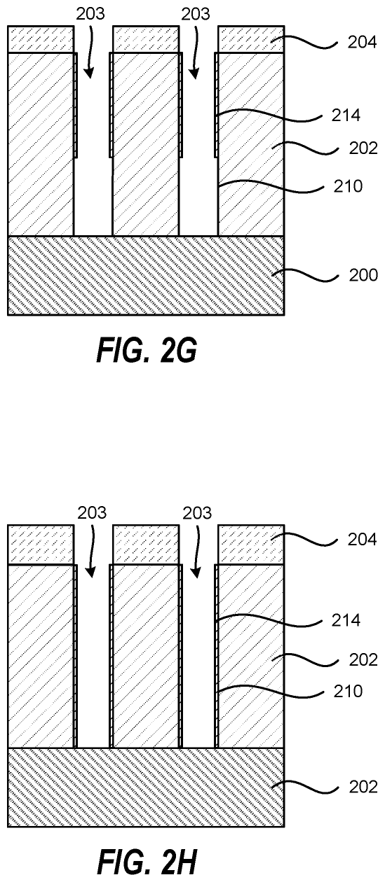

FIGS. 2A-2H schematically show through cross-sectional views a method of an anisotropic amorphous carbon layer etch with sidewall passivation according to an embodiment of the invention; and

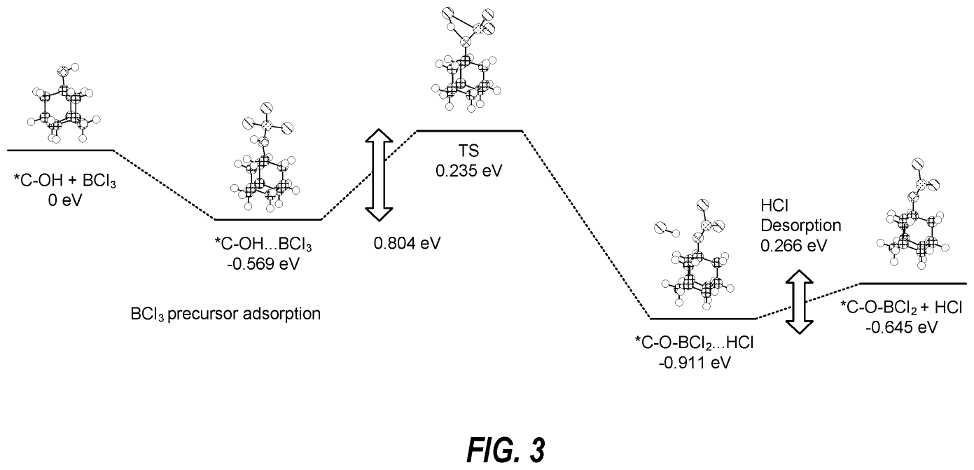

FIG. 3 schematically shows an energy level diagram for adsorption and thermal reaction of BCl₃ on a hydroxyl-terminated amorphous carbon layer to form a passivation layer according to an embodiment of the invention.

### DETAILED DESCRIPTION OF SEVERAL EMBODIMENTS

FIG. 1 schematically shows a plasma etching system according to one embodiment of the invention. The exemplary plasma etching system is a parallel-plate type plasma etching system where an upper electrode and a lower electrode (substrate holder) face each other in a chamber and a process gas is supplied through the upper electrode into the chamber.

The plasma etching system 1 includes a chamber 10 comprised of a conductive material such as aluminum and a gas supply 15 for supplying a process gas into the chamber 10. An appropriate process gas is selected according to the type of a mask, and the type of a target film (a film to be etched). The chamber 10 is electrically grounded. A lower electrode 20 and an upper electrode 25 are provided in the chamber 10. The upper electrode 25 is disposed in parallel with and to face the lower electrode 20. The lower electrode 20 also functions as a substrate holder for holding an object to be processed, i.e., a semiconductor substrate W on which a single-layer film or a multi-layer film is formed.

A power supply device 30 for supplying multi-frequency superposed power is connected to the lower electrode 20. The power supply device 30 includes a first high-frequency power supply 32 for supplying first radio-frequency (RF) power (plasma generation RF power) with a first frequency, and a second RF power supply 34 for supplying second RF power (bias voltage generation RF power) with a second frequency that is lower than the first frequency. The first RF power supply 32 is electrically connected via a first matching box 33 to the lower electrode 20. The second RF power supply 34 is electrically connected via a second matching box 35 to the lower electrode 20. Each of the first matching box 33 and the second matching box 35 makes the internal (or output) impedance of the corresponding one of the first RF power supply 32 and the second RF power supply 34 to match a load impedance. When plasma is being generated in the chamber 10, each of the first matching box 33 and the second matching box 35 makes the internal impedance of the corresponding one of the first high-frequency power supply 32 and the second high-frequency power supply 34 to apparently match the load impedance.

The upper electrode 25 is attached to a top portion of the chamber 10 via a shield ring 40 covering the periphery of the upper electrode 25. The upper electrode 25 may be electrically grounded as illustrated in FIG. 1. Alternatively, a variable direct-current power supply (not shown) may be connected to the upper electrode 25 so that a direct-current (DC) voltage is applied to the upper electrode 25.

A gas inlet 45 for introducing a gas from the gas supply 15 is formed in the upper electrode 25. Also, a diffusion chamber 50 is formed in the upper electrode 25 to diffuse a gas introduced via the gas inlet 45. Further, multiple gas supply holes 55 for supplying a gas from the diffusion chamber 50 into the chamber 10 are formed in the upper electrode 25. Through the gas supply holes 55, a process gas is supplied between the substrate W placed on the lower electrode 20 and the upper electrode 25. That is, a process gas from the gas supply 15 is first supplied via the gas inlet 45 into the diffusion chamber 50. Then, the process gas in the diffusion chamber 50 is distributed to the gas supply holes 55, and is ejected from the gas supply holes 55 toward the lower electrode 20. With the above configuration, the upper electrode 25 also functions as a gas showerhead for supplying a gas.

An evacuation port 60 is formed in the bottom of the chamber 10. An evacuation device 65 connected to the evacuation port 60 evacuates the chamber 10 and maintains the chamber 10 at a predetermined vacuum pressure. A gate valve G is provided on a side wall of the chamber 10. The gate valve G opens and closes a port for carrying the substrate W into and out of the chamber 10.

The plasma etching system 1 also includes a controller 100 for controlling operations of the entire plasma etching system 1. The controller 100 includes a central processing unit (CPU) 105, and storage areas including a read-only memory (ROM) 110 and a random access memory (RAM) 115. The CPU 105 performs a plasma etching process according to various recipes stored in the storage areas. A recipe includes control information for controlling the plasma etching system 1 to perform a process according to process conditions. For example, the control information includes a process time, a gas pressure in the chamber 10, high-frequency power and voltage, flow rates of various process gases (e.g., etching gases), and inner-chamber temperatures (e.g., an upper electrode temperature, a chamber side-wall temperature, and substrate holder temperature). Recipes indicating programs and process conditions may be stored in a hard disk or a semiconductor memory, or may be stored in a portable, computer-readable storage medium such as a CD-ROM or a DVD that is mounted on a predetermined position of a storage area.

Other plasma processing systems may be used to process the substrate W, including, but not limited to, an inductively coupled plasma (ICP) system, a capacitively coupled plasma (CCP) system, or a microwave-based plasma system.

A substrate processing method that includes plasma-etching and sidewall passivation of an amorphous carbon layer is described and may be performed by the exemplary plasma etching system 1 of the present embodiment. In this case, the gate valve G in FIG. 1 is first opened, and the substrate W on which a plurality films thereon is formed is provided into the chamber 10 and placed on the lower electrode 20 by, for example, a conveying arm (not shown). Next, the controller 100 controls components of the plasma etching system 1 to perform the desired process.

FIGS. 2A-2H schematically show through cross-sectional views a method of anisotropic amorphous carbon etch with sidewall passivation according to an embodiment of the invention. The method includes, in FIG. 2A, providing a substrate W containing a target film 200, an amorphous carbon layer (ACL) 202, a silicon oxynitride (SiON) film 204, a bottom antireflection coating (BARC) 206, and a photoresist (PR) film 208. In some examples, the target film 200 can include SiO₂ or SiN. In one example, the BARC 206 may be replaced by an organic dielectric layer (ODL). The film structure containing the PR film 208, the BARC/ODL 206, and the SiON 204 is a non-limiting example of a mask layer structure for anisotropic etching of the ACL 202.

The ACL 202 serves as a mask layer for subsequent anisotropic etching of the target film 200 and also functions as a lower-layer resist film. A thickness of the ACL 202 can, for example, be between about 200 nm and about 5000 nm, between about 1000 nm and about 5000 nm, or between about 2000 nm and about 4000 nm. On the ACL 202, the SiON film 204 is formed by, for example, a chemical vapor deposition (CVD) process or a physical vapor deposition (PVD) process. On the SiON film 204, the BARC 206 is formed by, for example, a spin coater. Further, the PR film 208 is formed on the BARC 206 by using, for example, a spin coater. The BARC 206 can include a polymer resin including a pigment that absorbs light with a specific wavelength such as an ArF excimer laser beam emitted toward the PR film 208. The BARC 206 prevents the ArF excimer laser beam, which passes through the PR film 208, from being reflected by the SiON film 204 or the ACL 202 and reaching the PR film 208 again. The PR film 208 includes, for example, a positive photosensitive resin and is altered to have alkali solubility when illuminated by the ArF excimer laser beam.

Thereafter, the method includes patterning the PR film 208 using a known photolithography technology, and plasma-etching the BARC 206 and the SiON film 204 using the patterned PR film 208 as a mask. In one example, an etching gas containing a mixture of a fluorocarbon (CF) gas (e.g., carbon tetrafluoride (CF₄)) and an oxygen (O₂) gas may be used to achieve high etching rate of the BARC 206 and the SiON film 204. FIG. 2B shows a resulting patterned mask 212 containing openings 201, following removal of the remainder of the PR film 208. For example, the openings 201 can include a trench or a hole (via). Examples of a critical diameter (CD) for trenches are about 100 nm, and about 60 nm for vias. The materials of the patterned mask 212 described above are exemplary and other materials that provide etch selectivity to the ACL 202 may be used.

Next, as schematically shown in FIG. 2C, the ACL 202 is etched by plasma-etching according to the opening 201 of the patterned mask 212. In one example, an etching gas containing a sulfur(S)-containing gas may be used. For example, a mixture of O₂ gas and carbonyl sulfide (COS) gas, or a mixture of O₂ gas and sulfur dioxide (SO₂) gas, may be used to form recessed features 203 in the ACL 202. These gases provide good etch selectivity to several patterned masks, including SiO₂, SiN, and SiON. The etching gas can further with include Ar, He, Xe, Ne, N₂, CO, CO₂, or a combination thereof. The etching gas can contain a mixture of these gases in any ratio. In the embodiment shown in FIG. 2C, the recessed feature 203 includes a sidewall 210 that extends through less than an entire thickness of the ACL 202.

Thereafter, as shown in FIG. 2D, the method further includes forming a passivation layer 214 on the sidewall 210 and other surfaces of the etched ACL 202 in the recessed feature 203 by exposing the substrate to a passivation gas in the absence of a plasma. The processing conditions can include a chamber gas pressure between about 5 mTorr and about 1 atm, and a substrate temperature between about −100° C. and about 200° C. According to one embodiment, the plasma-etching and the forming the passivation layer may carried out in the same chamber, for example the chamber 10 in FIG. 1. According to another embodiment, the plasma-etching and the forming the passivation layer may carried out in different chambers.

The passivation gas may be selected to thermally react in the absence of plasma excitation with exposed surfaces of the ACL 202 in the recessed feature 203, including the sidewall 210, with good selectivity to the patterned mask 212. However, good selectivity to the patterned mask is not required. Further, the absence of plasma-excitation during the gas exposure results in conformal coverage of the passivation layer 214 in the recessed feature 203, where the formation of the passivation layer 214 is self-limiting.

According to embodiments of the invention, the passivation gas can contain a boron-containing gas, a silicon-containing gas, an aluminum-containing gas, or a combination thereof. The boron-containing gas can, for example, include BCl₃, BH₃, or BBr₃. The silicon-containing gas can, for example, include SiClₓH₄₋ₓ (x=0-4) or Si₂ClₓH₆₋ₓ (x=0-6). The aluminum-containing gas can, for example, include AlCl₃ or AlFₓ(CH₃)₃₋ₓ. where x=0-2. The passivation gas can further include an inert gas (e.g., Ar, He, or N₂). The total gas flow rate can, for example, be between about 1 sccm and about 5000 sccm.

The method further includes, repeating the plasma-etching of the ACL 202 and formation of the passivation layer 214 at least once to extend the recessed feature 203 in the ACL 202. Repeating the plasma-etching of the ACL 202 results in the structure shown in FIG. 2E, where the recessed feature 202 extends below the passivation layer 214.

The presence of the passivation layer 214 reduces or prevents problematic “bowing” where a cross-section of the recessed feature 203 in the ACL 202 in a direction perpendicular to the thickness direction of the ACL 202 becomes wider than a cross-section of an opening of the patterned mask 212.

Thereafter, repeating the formation of the passivation layer 214 results in the structure shown in FIG. 2F, where the passivation layer 214 is formed on the exposed surfaces of the recessed feature 203, including on the new surfaces created by the plasma-etching. Further repeating the plasma-etching of the ACL 202 and repeating the formation of the passivation layer 214 until the recessed feature 203 extends through the entire ACL 202 results in the structures shown in FIGS. 2G and 2H, respectively. The duration of each cycle of the plasma-etching and forming the passivation layer may be varied in order to provide acceptable etch rates and protection of the sidewall 210 in the recessed feature 203. Further, the process parameters of the plasma-etching of the ACL 202 may be varied as needed.

According to one embodiment, the formation of the passivation layer 214 shown in FIG. 2H may be omitted once the recessed feature 203 extends through the entire thickness of the ACL 202 as shown in FIG. 2G. In other words, the number of times the forming the passivation layer is repeated can be one less than the number of times the plasma etching is repeated.

In one process example, an amorphous carbon layer having a thickness of about 3000 nm was plasma etched using a patterned mask to form recessed features through the entire thickness of the amorphous carbon layer. The use of a passivation layer formed by BCl₃ gas exposure reduced the CD from about 101 nm to about 93 nm at the depth midpoint.

FIG. 3 schematically shows an energy level diagram for adsorption and thermal reaction of BCl₃ on a hydroxyl-terminated amorphous carbon layer to form a passivation layer. The formation of C—O—BCl₂ surface species as a passivation layer on the amorphous carbon layer by BCl₃ gas exposure is thermodynamically favorable by about −0.645 eV. Experimental data further showed that plasma-etching of an amorphous carbon layer forms hydroxyl species (—OH) as an etch by-product. The formation of the passivation layer is self-limiting and conformal since the C—OH is only present at the surface and only C—OH provides the active side for the precursor (e.g. BCl₃) to bind and form chemical bonds (C—O—BCl₂).

Methods for an anisotropic amorphous carbon layer etch with side-wall passivation for semiconductor manufacturing been disclosed in various embodiments. The foregoing description of the embodiments of the invention has been presented for the purposes of illustration and description. It is not intended to be exhaustive or to limit the invention to the precise forms disclosed. This description and the claims following include terms that are used for descriptive purposes only and are not to be construed as limiting. Persons skilled in the relevant art can appreciate that many modifications and variations are possible in light of the above teaching. Persons skilled in the art will recognize various equivalent combinations and substitutions for various components shown in the Figures. It is therefore intended that the scope of the invention be limited not by this detailed description, but rather by the claims appended hereto.

1. An etching method, comprising:
providing a substrate containing an amorphous carbon layer and a patterned mask layer;
plasma-etching a recessed feature through less than an entire thickness of the amorphous carbon layer using the patterned mask;
forming a passivation layer on a sidewall of the etched amorphous carbon layer in the recessed feature by exposing the substrate to a passivation gas in the absence of a plasma; and
repeating the plasma-etching and forming the passivation layer at least once to extend the recessed feature in the amorphous carbon layer.

2. The method of claim 1, wherein the repeating is performed until the recessed feature extends through the entire thickness of the amorphous carbon layer.

3. The method of claim 2, wherein the number of times the forming the passivation layer is repeated is one less than the number of times the plasma etching is repeated.

4. The method of claim 1, wherein the plasma-etching includes exposing the substrate to an etching gas containing a sulfur-containing gas and O₂ gas.

5. The method of claim 4, wherein the sulfur-containing gas includes SO₂, COS, or a mixture thereof.

6. The method of claim 1, wherein the passivation gas includes a boron-containing gas, a silicon-containing gas, or an aluminum-containing gas.

7. The method of claim 6, wherein the boron-containing gas includes BCl₃, BH₃, or BBr₃.

8. The method of claim 6, wherein the silicon-containing gas includes SiClₓH₄₋ₓ (x=0-4) or Si₂ClₓH₆₋ₓ (x=0-6).

9. The method of claim 6, wherein the aluminum-containing gas includes AlCl₃ or AlFₓ(CH₃)₃₋ₓ, where x=0-2.

10. An etching method, comprising:
providing a substrate containing an amorphous carbon layer and a patterned mask layer;
plasma-etching a recessed feature through less than an entire thickness of the amorphous carbon layer using the patterned mask;
forming a passivation layer on a sidewall of the etched amorphous carbon layer in the recessed feature by exposing the substrate to a passivation gas containing BCl₃ in the absence of a plasma; and
repeating the plasma-etching and forming the passivation layer at least once to extend the recessed feature in the amorphous carbon layer.

11. The method of claim 10, wherein the repeating is performed until the recessed feature extends through the entire thickness of the amorphous carbon layer.

12. The method of claim 11, wherein the number of times the forming the passivation layer is repeated is one less than the number of times the plasma etching is repeated.

13. The method of claim 10, wherein the plasma-etching includes exposing the substrate to an etching gas containing a sulfur-containing gas.

14. The method of claim 13, wherein the sulfur-containing gas includes SO₂, COS, or a mixture thereof.

15. An etching method, comprising:
providing a substrate containing an amorphous carbon layer and a patterned mask layer;
plasma-etching a recessed feature through less than an entire thickness of the amorphous carbon layer using the patterned mask;
forming a passivation layer on a sidewall of the etched amorphous carbon layer in the recessed feature by exposing the substrate to a passivation gas containing BCl₃ in the absence of a plasma; and
repeating the plasma-etching and forming the passivation layer at least once until the recessed feature extends through the entire thickness of the amorphous carbon layer.

16. The method of claim 15, wherein the number of times the forming the passivation layer is repeated is one less than the number of times the plasma etching is repeated.

17. The method of claim 15, wherein the plasma-etching includes exposing the substrate to an etching gas containing a sulfur-containing gas.

18. The method of claim 17, wherein the sulfur-containing gas includes SO₂, COS, or a mixture thereof.
